(19) United States
(12) Patent Application Publication
(10) Pub. No.: US 2013/0155753 A1
(43) Pub. Date: Jun. 20, 2013

(54) METHOD FOR IMPLEMENTING SPARE LOGIC OF SEMICONDUCTOR MEMORY APPARATUS AND STRUCTURE THEREOF

(71) Applicants: Young Suk MOON, Icheon-si (KR); Yong Kee KWON, Icheon-si (KR)

(72) Inventors: Young Suk MOON, Icheon-si (KR); Yong Kee KWON, Icheon-si (KR)

(73) Assignee: SK HYNIX INC., Icheon-si (KR)

(21) Appl. No.: 13/585,455

(22) Filed: Aug. 14, 2012

(30) Foreign Application Priority Data
Dec. 19, 2011 (KR) 10-2011-0137486

(51) Int. Cl. G11C 5/06

(52) U.S. Cl. 365/72; 365/63

(57) ABSTRACT

A method for implementing a spare logic of a semiconductor memory apparatus includes the steps of: forming one or more contact conductive layers, which are independent, in a power line and an active area, respectively; and performing metal programming on the contact conductive layers formed in the power line and the active area to electrically couple the independent contact conductive layers formed in the power line and the active area.

### CROSS-REFERENCES TO RELATED APPLICATION

The present application claims priority under 35 U.S.C. §119(a) to Korean application number 10-2011-0137486, filed on Dec. 19, 2011 in the Korean Intellectual Property Office, which is incorporated herein by reference in its entirety.

### BACKGROUND

1. Technical Field

The present invention relates to a method for fabricating a semiconductor memory apparatus and a structure thereof, and more particularly, to a method for implementing a spare logic of a semiconductor memory apparatus and a structure thereof.

2. Related Art

In general, semiconductor memory apparatuses used for storing data may be divided into a volatile memory apparatus and a nonvolatile memory apparatus. First, the volatile memory apparatus represented by DRAM or SRAM quickly inputs and outputs data, but loses data stored therein as power supply is cut off. Furthermore, since DRAM requires a periodic refresh operation and a high charge storage capacity, many attempts have been made to increase capacitance.

The nonvolatile memory apparatus represented by a NAND or NOR-type flash memory based on EEP ROM (Electrically Erasable Programmable Read Only Memory) maintains data stored therein, even though power supply is cut off. Such a nonvolatile memory apparatus has a gate pattern including a gate dielectric layer, a floating gate, a dielectric layer, and a control gate which are sequentially stacked over a semiconductor substrate.

Data are written into or erased from the nonvolatile memory apparatus by applying tunnel charges through the gate dielectric layer. At this time, a higher operating voltage than a typical power supply voltage is required to perform these operations. Accordingly, since flash memory devices need a boosting circuit configured to form a voltage required for writing/erasing data, the design rule inevitably increases.

Therefore, with the rapid development in the information communication field and the rapid popularization of information media such as computers, demand is increasing for a next-generation memory apparatus which operates at ultrahigh speed and has a large memory storage capacity for processing functions.

Next-generation memory apparatuses have been developed by using advantages of volatile memory apparatuses such as DRAM and the nonvolatile memory apparatus such as flash memory. The next-generation memory apparatus consumes a small amount of power during operation, and has excellent characteristics in terms of data maintenance and read/write operations. The next-generation memory apparatus may include FRAM (Ferroelectric Random Access Memory), MRAM (Magnetic Random Access Memory), PRAM (Phase-change Random Access Memory), NFGM (Nano Floating Gate Memory) among others.

When the above-described semiconductor memory apparatuses are fabricated, a system for fabricating the apparatus is first chosen, and circuits for performing functions related to the chosen system are schematically designed. Then, the designed circuits are verified, and a placing and rounding operation is performed. When verification for the layout is completed, a mask of an integrated circuit is created.

Therefore, when the integrated circuit is fabricated, spare logic devices, that is, spare logics are additionally designed into the integrated circuit, in order to prepare for a case where a mask forming a transistor within the integrated circuit is to be changed. Furthermore, when an ECO (Engineer Change Order) is given, the spare logics are used according to the ECO. Furthermore, when spare logics exist in the integrated circuit as described above, when the circuit design is revised, metals acting as conductive deposition materials are corrected without correcting the mask forming the transistor within the integrated circuit.

FIG. 1 is the layout of spare logics of a conventional semiconductor memory apparatus, illustrating basic gates which are considered to be required for logic correction according to a designer's decision.

Referring to FIG. 1, nine INV gates 1a, 1b, 1c, 1d, 1e, 1f, 1g, 1h, and 1i and seven ND2 gates 2a, 2b, 2c, 2d, 2e, 2f, and 2g are formed adjacent to each other. The plurality of INV gates 1a to 1i, and ND2 gates 2a to 2g are spare logics formed to prepare for circuit design revision, and are coupled to each other through metal programming according to a designer's revision intention during circuit design revision, thereby implementing a variety of gates.

FIG. 2 illustrates an example in which the spare logics illustrated in FIG. 1 are utilized.

Referring to FIG. 2, the spare logics illustrated in FIG. 1 are implemented as two NAND4 gates according to circuit design revision. That is, four INV gates 1a, 1b, 1c, and 1d and six ND2 gates 2a, 2b, 2c, 2d, 2e, and 2f are coupled through metals, in order to implement the two NAND4 gates.

However, when a NAND4 gate is additionally required in a state where the two NAND4 gates were formed, a NAND4 gate cannot be implemented because the number of INV gates is sufficient but the number of ND2 gates is insufficient. In this case, a full revision should be performed instead of a metal revision. Accordingly, not only does design time increase, but a significant cost is also required.

### SUMMARY

In one embodiment of the present invention, a method for implementing a spare logic of a semiconductor memory apparatus includes the steps of: forming one or more contact conductive layers, which are independent, in a power line and an active area, respectively; and performing metal programming on the contact conductive layers formed in the power line and the active area to electrically couple the contact conductive layers formed in the power line and the active area.

In another embodiment of the present invention, a spare logic of a semiconductor memory apparatus includes: a power line having one or more contact conductive layers formed therein, on which metal programming is to be performed; and an active area having one or more contact conductive layers formed therein, which are configured to be electrically coupled to the one or more contact conductive layers of the power line through the metal programming.

### BRIEF DESCRIPTION OF THE DRAWINGS

Features, aspects, and embodiments are described in conjunction with the attached drawings, in which:

FIG. 1 is the layout of spare logics of a conventional semiconductor memory apparatus;

FIG. 2 illustrates an example in which the spare logics illustrated in FIG. 1 are utilized;

FIG. 3 illustrates a structure of a super cell according to one embodiment;

FIG. 4 illustrates logic of a super cell having an INV gate implemented therein and a logic circuit thereof according to an embodiment;

FIG. 5 illustrates logic of a super cell having a NAND2 gate implemented therein and a logic circuit thereof according to an embodiment;

FIG. 6 illustrates logic of a super cell having a NOR2 gate implemented therein and a logic circuit thereof according to an embodiment;

FIG. 7 illustrates logic of a super cell having a NAND3 gate implemented therein and a logic circuit thereof according to an embodiment;

FIG. 8 illustrates logic of a super cell having a NOR3 gate implemented therein and a logic circuit thereof according to an embodiment;

FIG. 9 illustrates logic of a super cell having a NAND4 gate implemented therein and a logic circuit thereof according to an embodiment;

FIG. 10 illustrates logic of a super cell having a NOR4 gate implemented therein and a logic circuit thereof according to an embodiment;

FIG. 11 illustrates logic of a super cell having a NAND-NAND gate combination (NAND2+NAND2) implemented therein and a logic circuit thereof according to an embodiment;

FIG. 12 illustrates logic of a super cell having a NOR-NOR gate combination (NOR2+NOR2) implemented therein and a logic circuit thereof according to an embodiment;

FIG. 13 illustrates logic of a super cell having a NAND-NOR gate combination (NAND2+NOR2) implemented therein and a logic circuit thereof according to an embodiment;

FIG. 14 illustrates logic of a super cell having a NAND-INV gate combination (NAND3+INV) implemented therein and a logic circuit thereof according to an embodiment;

FIG. 15 illustrates logic of a super cell having a NOR-INV gate combination (NOR3+INV) implemented therein and a logic circuit thereof according to an embodiment;

FIG. 16 illustrates the layout of super cells according to an embodiment; and

FIG. 17 illustrates an example in which the super cells of FIG. 16 are utilized.

### DETAILED DESCRIPTION

Hereinafter, a method for implementing spare logic of a semiconductor memory apparatus and a structure thereof according to embodiments of the present invention will be described below with reference to the accompanying drawings through example embodiments.

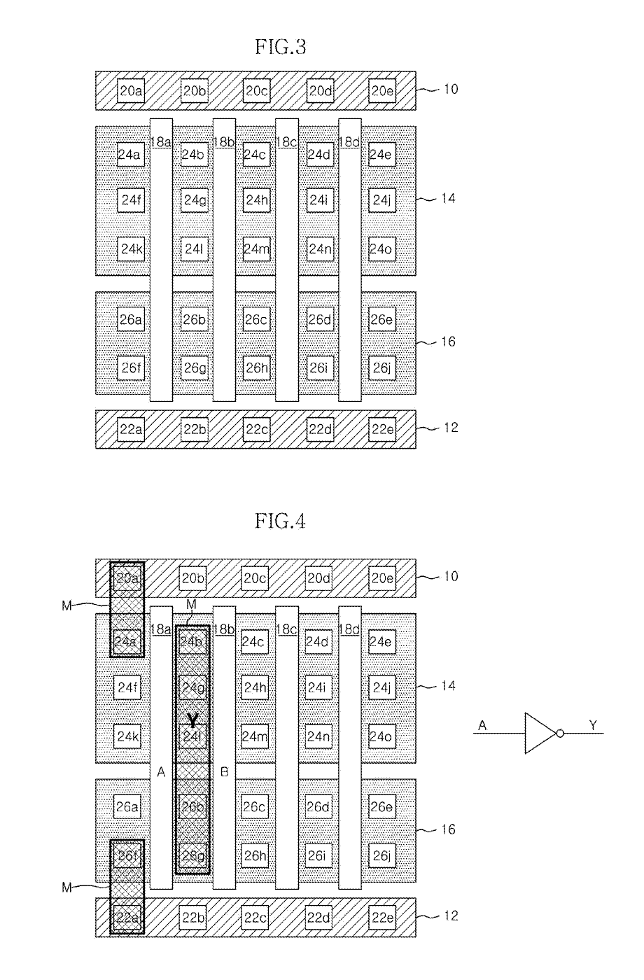

FIG. 3 illustrates the structure of a super cell according to one embodiment.

Referring to FIG. 3, a VDD line 10 and a VSS line 12 are formed as power lines. Furthermore, a PMOS active area 14 and an NMOS active area 16 are formed between the VDD line 10 and the VSS line 12. Furthermore, gates 18a, 18b, 18c, and 18d functioning as input terminals are formed on the PMOS active area 14 and the NMOS active area 16.

The VDD line 10 includes five contact conductive layers 20a, 20b, 20c, 20d, and 20e formed thereon, and the VSS line 12 also includes five contact conductive layers 22a, 22b, 22c, 22d, and 22e formed thereon. Furthermore, the PMOS active area 14 includes contact conductive layers 24a, 24b, 24c, 24d, 24e, 24f, 24g, 24h, 24i, 24j, 24k, 24l, 24m, 24n, and 24o formed in a 3×5 matrix among the four gates 18a, 18b, 18c, and 18d, and the NMOS active area 16 includes contact conductive layers 26a, 26b, 26c, 26d, 26e, 26f, 26g, 26h, 26i, and 26j formed in a 2×5 matrix among the four gates 18a, 18b, 18c, and 18d.

The contact conductive layers (VDD line-20a to 20e, VSS line-22a to 22e, PMOS active area-24a to 24o, and NMOS active area-26a to 26j) formed in the VDD line 10, the VSS line 12, the PMOS active area 14, and the NMOS active area 16 indicate preliminary contacts which are to be electrically coupled by metal programming during subsequent circuit design revision. That is, in a state where circuit design revision is not performed, as illustrated in FIG. 3, the contact conductive layers do not function as contacts, because they are independent conductive layers which are isolated by other material layers. However, when circuit design revision is performed in the future, a metal is coupled to the contact conductive layers according to a designer's intention, thereby implementing various gates based on the designer's intention. Here, the number of contact conductive layers formed in the VDD line 10, the VSS line 12, the PMOS active area 14, and the NMOS active area 16 may be set to one or more, according to the designer's intention or the design rule.

According to an embodiment, the contact conductive layers are formed in the power lines and the active areas before circuit design revision, in order to prepare for the circuit design revision. Furthermore, during actual circuit design revision, various gates may be implemented through a metal programming process for adjusting the formation positions of metals which may be done to couple the contact conductive layers, which may make it possible to freely and easily change the logic of the super cell.

FIGS. 4 to 15 illustrate various embodiments of the super cell illustrated in FIG. 3. FIGS. 4 to 10 illustrate example embodiments in which one logic is realized in one super cell, and FIGS. 11 to 15 illustrate examples of gate combinations in which two logics are actualized in one super cell.

FIG. 4 illustrates logic of a super cell having an INV gate implemented therein and a logic circuit thereof according to an embodiment.

Referring to FIG. 4, the contact conductive layer 20a of the VDD line 10 and the contact conductive layer 24a positioned in the first row and first column of the PMOS active area 14 to the left side of the first gate 18a are coupled through a metal M.

Furthermore, the contact conductive layer 22a of the VSS line 12 and the contact conductive layer 26f positioned in the second row and first column of the NMOS active area 16 to the left side of the first gate 18a are coupled through a metal M. Here, the first gate 18a serves as a signal input terminal A.

Furthermore, when the contact conductive layers 24b, 24g, and 24l positioned in the second column of the PMOS active area 14 and the contact conductive layers 26b and 26g positioned in the second column of the NMOS active area 16 are coupled through a metal M, the INV gate having one signal input terminal A and one signal output terminal Y is actualized in the super cell.

FIG. 5 illustrates logic of a super cell having a NAND2 gate implemented therein and a logic circuit thereof according to an embodiment.

Referring to FIG. 5, the contact conductive layer 20a of the VDD line 10 and the contact conductive layer 24a positioned in the first row and first column of the PMOS active area 14 to the left side of the first gate 18a are coupled through a metal M. Furthermore, the contact conductive layer 20c of the VDD line 10 and the contact conductive layer 24c positioned in the first row and third column of the PMOS active area 14 on the right side of the second gate 18b are coupled through a metal M.

Furthermore, the contact conductive layer 22c of the VSS line 12 and the contact conductive layer 26h positioned in the second row and third column of the NMOS active area 16 to the right side of the second gate 18b are coupled through a metal M. Here, the first gate 18a and the second gate 18b serve as a signal input terminal A and a signal input terminal B, respectively.

Furthermore, when the contact conductive layers 24b, 24g, and 24l positioned at the second column of the PMOS active area 14 and the contact conductive layers 26a and 26f positioned at the first column of the NMOS active area 16 are coupled through a metal M, the NAND2 gate having two signal input terminals A and B and one signal output terminal Y is actualized in the super cell.

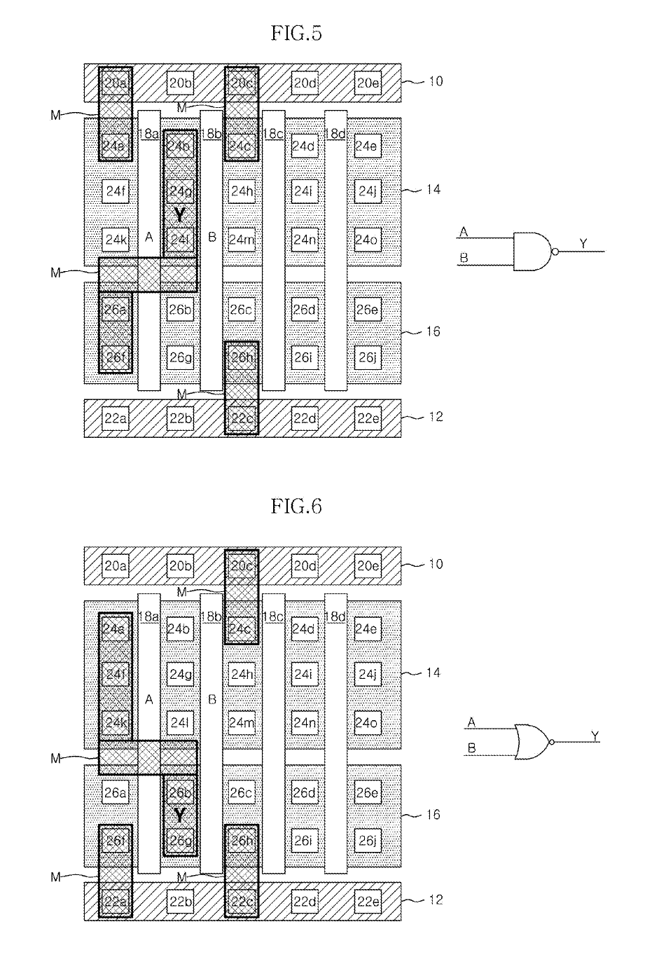

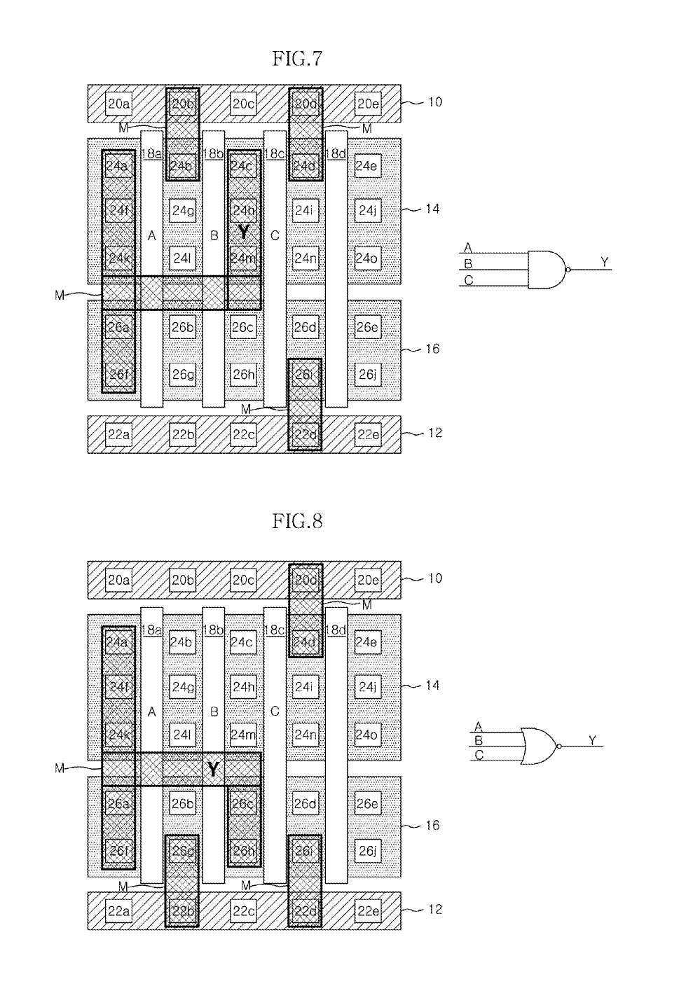

FIG. 6 illustrates logic of a super cell having a NOR2 gate implemented therein and a logic circuit thereof according to the embodiment.

Referring to FIG. 6, the contact conductive layer 20c of the VDD line 10 and the contact conductive layer 24c positioned in the first row and third column between second and third gates 18b and 18c of a PMOS active area 14 are coupled through a metal M.

Furthermore, the contact conductive layer 22a of the VSS line 12 and the contact conductive layer 26f positioned in the second row and first column of the NMOS active area 16 to the left side of the first gate 18a are coupled through a metal M. Here, the first and second gates 18a and 18b serve as a signal input terminal A and a signal input terminal B, respectively.

Furthermore, when the contact conductive layers 24a, 24f, and 24k positioned in the first column of the PMOS active area 14 and the contact conductive layers 26b and 26g positioned in the second column of the NMOS active area 16 are coupled through a metal M, a NOR2 gate having two signal input terminals A and B and one signal output terminal Y is actualized in the super cell.

FIG. 7 illustrates logic of a super cell having a NAND3 gate implemented therein and a logic circuit thereof according to the embodiment.

Referring to FIG. 7, the contact conductive layer 20b of the VDD line 10 and the contact conductive layer 24b positioned in the first row and second column of the PMOS active area 14 between the first and second gates 18a and 18b are coupled through a metal M. The contact conductive layer 20d of the VDD line 10 and the contact conductive layer 24d positioned at the first row and fourth column of the PMOS active area 14 between the third and fourth gates 18c and 18d are coupled through a metal M.

Furthermore, the contact conductive layer 22d of the VSS line 12 and the contact conductive layer 26i positioned in the second row and fourth column of the NMOS active area 16 between the third and fourth gates 18c and 18d are coupled through a metal M. Here, the first gate 18a, the second gate 18b, and the third gate 18c serve as a signal input terminal A, a signal input terminal B, and a signal input terminal C, respectively.

Furthermore, when the contact conductive layers 24a, 24f, and 24k positioned in the first column of the PMOS active area 14 and the contact conductive layers 24c, 24h, and 24m positioned in the third column are coupled to the contact conductive layers 26a and 26f positioned in the first column of the NMOS active area 16 through a metal M, the NAND3 gate having three signal input terminals A, B, and C and one signal output terminal Y is actualized in the super cell.

FIG. 8 illustrates logic of a super cell having a NOR3 gate implemented therein and a logic circuit thereof according to an embodiment.

Referring to FIG. 8, the contact conductive layer 20d of the VDD line 10 and the contact conductive layer 24d positioned in the first row and fourth column of the PMOS active area 14 between the third and fourth gates 18c and 18d are coupled through a metal M.

Furthermore, the contact conductive layer 22b of the VSS line 12 and the contact conductive layer 26g positioned in the second row and second column of the NMOS active area 16 between the first and second gates 18a and 18b are coupled through a metal M. Furthermore, the contact conductive layer 22d of the VSS line 12 and the contact conductive layer 26i positioned at the second row and fourth column of the NMOS active area 16 between the third and fourth gates 18c and 18d are coupled through a metal M. Here, the first gate 18a, the second gate 18b, and the third gate 18c serve as a signal input terminal A, a signal input terminal B, and a signal input terminal C, respectively.

Furthermore, when the contact conductive layers 24a, 24f, and 24k positioned in the first column of the PMOS active area 14, the contact conductive layers 26a and 26f positioned in the first column of the NMOS active area 16, and the contact conductive layers 26c and 26h positioned in the third column of the NMOS active area 16 are coupled through a metal M, the NOR3 gate having three signal input terminals A, B, and C and one signal output terminal Y is actualized in the super cell.

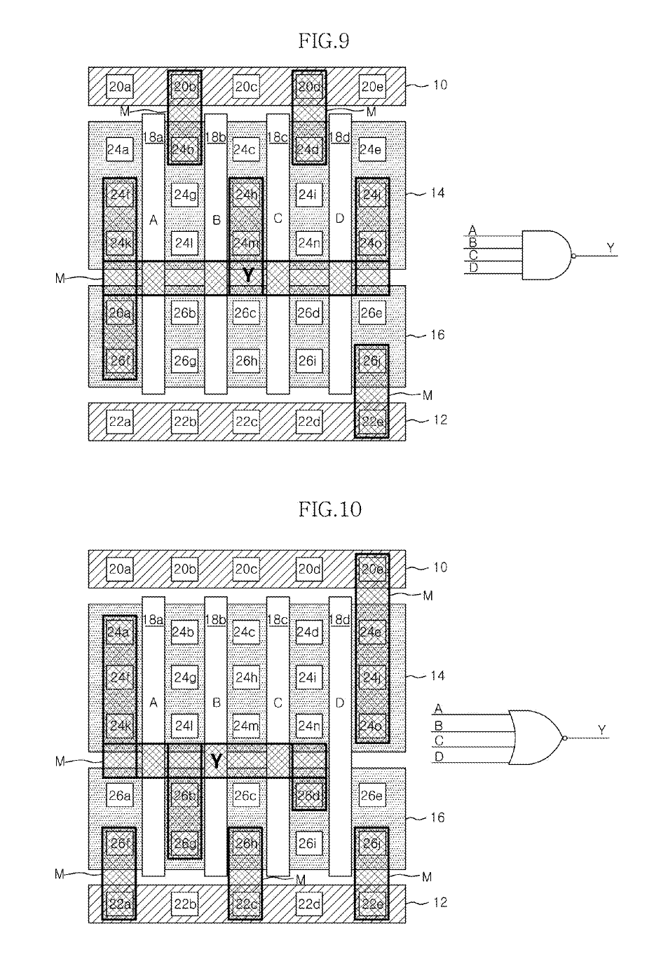

FIG. 9 illustrates logic of a super cell having a NAND4 gate implemented therein and a logic circuit thereof according to an embodiment.

Referring to FIG. 9, the contact conductive layer 20b of the VDD line 10 and the contact conductive layer 24b positioned in the first row and second column of the PMOS active area 14 between the first and second gates 18a and 18b are coupled through a metal M. Furthermore, the contact conductive layer 20d of the VDD line 10 and the contact conductive layer 24d positioned in the first row and fourth column of the PMOS active area 14 between the third and fourth gates 18c and 18d are coupled through a metal M.

Furthermore, the contact conductive layer 22e of the VSS line 12 and the contact conductive layer 26j positioned in the second row and fifth column of the NMOS active area 16 to the right side of the fourth gate 18d are coupled through a metal M.

Here, the first gate 18a, the second gate 18b, the third gate 18c, and the fourth gate 18d serve as a signal input terminal A, a signal input terminal B, a signal input terminal C, and a signal input terminal D, respectively.

Furthermore, when the contact conductive layers 24f and 24k positioned in the first column of the PMOS active area 14, the contact conductive layers 24h and 24m positioned in the third column of the PMOS active area 14, and the contact conductive layers 24j and 24o positioned in the fifth column of the PMOS active area 14 are coupled to the contact conductive layers 26a and 26f positioned in the first column of the NMOS active area 16 through a metal M, the NAND4 gate having four signal input terminals A, B, C, and D and one signal output terminal Y is realized in the super cell.

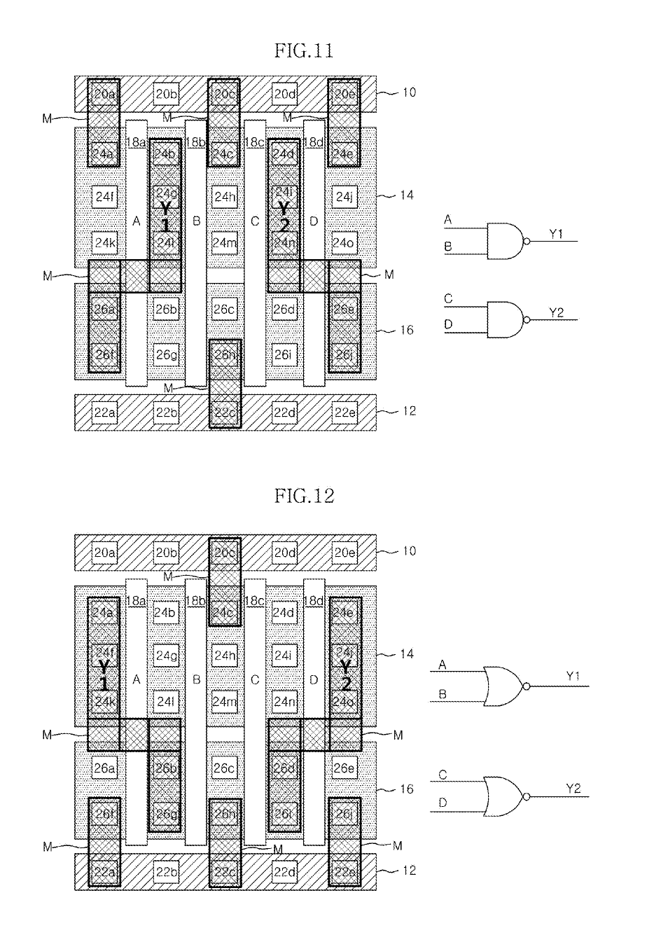

FIG. 10 illustrates logic of a super cell having a NOR4 gate implemented therein and a logic circuit thereof according to an embodiment.

Referring to FIG. 10, the contact conductive layer 20e of the VDD line 10 and the contact conductive layers 24e, 24j, and 24o positioned in the fifth column of the PMOS active area 14 to the right side of the fourth gate 18d are coupled through a metal M.

Furthermore, the contact conductive layer 22a of the VSS line 12 and the contact conductive layer 26f positioned in second row and the first column of the NMOS active area 16 to the left side of the first gate 18a are coupled through a metal M. Furthermore, the contact conductive layer 22c of the VSS line 12 and the contact conductive layer 26h positioned in the second row and third column of the NMOS active area 16 between the second and third gates 18b and 18c are coupled through a metal M. Furthermore, the contact conductive layer 22e of the VSS line 12 and the contact conductive layer 26j positioned in the second row and fifth column of the NMOS active area 16 to the right side of the fourth gate 18d are coupled through a metal M.

Here, the first gate 18a, the second gate 18b, the third gate 18c, and the fourth gate 18d serve as a signal input terminal A, a signal input terminal B, a signal input terminal C, and a signal input terminal D, respectively.

Furthermore, when the contact conductive layers 24a, 24f, and 24k positioned in the first column of the PMOS active area 14, the contact conductive layers 26b and 26g positioned in the second column of the NMOS active area 16, and the contact conductive layer 26d positioned in the first row and fourth column of the NMOS active area 16 are coupled through a metal M, the NOR4 gate having four signal input terminals A, B, C, and D and one signal output terminal Y is actualized in the super cell.

FIGS. 11 to 15 illustrate examples of gate combinations in which two logics are actualized in one super cell.

FIG. 11 illustrates logic of a super cell having a NAND-NAND gate combination (NAND2+NAND2) implemented therein and a logic circuit thereof according to an embodiment.

Referring to FIG. 11, the contact conductive layer 20a of the VDD line 10 and the contact conductive layer 24a positioned in the first row and first column of the PMOS active area 14 to the left side of the first gate 18a are coupled through a metal M. Furthermore, the contact conductive layer 20c of the VDD line 10 and the contact conductive layer 24c positioned in the first row and third column of the PMOS active area 14 to the right side of the second gate 18b are coupled through a metal M. Furthermore, the contact conductive layer 22c of the VSS line 12 and the contact conductive layer 26h positioned in the second row and third column of the NMOS active area 16 between the second and third gates 18b and 18c are coupled through a metal M. Here, the first gate 18a and the second gate 18b serve as a signal input terminal A and a signal input terminal B, respectively.

Furthermore, when the contact conductive layers 24b, 24g, and 24l positioned in the second column of the PMOS active area 14 and the contact conductive layers 26a and 26f positioned in the first column of the NMOS active area 16 are coupled through a metal M, a first NAND2 gate having two signal input terminals A and B and one signal output terminal Y1 is realized.

The contact conductive layer 20e of the VDD line 10 and the contact conductive layer 24e positioned in the first row and fifth column to the right side of the fourth gate 18d of the PMOS active area 14 are coupled through a metal M.

Furthermore, when the contact conductive layers 24d, 24i, and 24n positioned in the fourth column of the PMOS active area 14 between the third and fourth gates 18c and 18d and the contact conductive layers 26e and 26j positioned in the fifth column of the NMOS active area 16 are coupled through a metal M, a second NAND2 gate having two signal input terminals C and D and one signal output terminal Y2 is actualized.

Here, when the second NAND2 gate forms a symmetrical structure with the first NAND2 gate, the NAND-NAND gate combination (NAND2+NAND2) having two NAND gates is actualized in the super cell.

FIG. 12 illustrates logic of a super cell having a NOR-NOR gate combination (NOR2+NOR2) implemented therein and a logic circuit thereof according to an embodiment.

Referring to FIG. 12, the contact conductive layer 20c of the VDD line 10 and the contact conductive layer 24c positioned in the first row and third column of the PMOS active area 14 between the second and third gates 18b and 18c are coupled through a metal M.

Furthermore, the contact conductive layer 22a of the VSS line 12 and the contact conductive layer 26f positioned in the second row and first column of the NMOS active area 16 to the left side of the first gate 18a are coupled through a metal M. Furthermore, the contact conductive layer 22c of the VSS line 12 and the contact conductive layer 26h positioned in the second row and third column of the NMOS active area 16 between the second and third gates 18b and 18c are coupled through a metal M. Here, the first gate 18a and the second gate 18b serve as a signal input terminal A and a signal input terminal B, respectively.

Furthermore, when the contact conductive layers 24a, 24f, and 24k positioned in the first column of the PMOS active area 14 and the contact conductive layers 26b and 26g positioned in the second column of the NMOS active area 16 are coupled through a metal M, a first NOR2 gate having two signal input terminals A and B and one signal output terminal Y1 is actualized.

The contact conductive layer 22e of the VSS line 12 and the contact conductive layer 26j positioned in the second row and fifth column of the NMOS active area 16 to the right side of the fourth gate 18d are coupled through a metal M.

Furthermore, when the contact conductive layers 24e, 24j, and 24o positioned in the fifth column of the PMOS active area 14 to the right side of the fourth gate 18d and the contact conductive layers 26d and 26i positioned in the fourth column of the NMOS active area 16 between the third and fourth gates 18c and 18d are coupled through a metal M, a second NOR2 gate having two signal input terminals C and D and one signal output terminal Y2 is actualized.

Here, as the second NOR2 gate forms a symmetrical structure with the first NOR2 gate, the NOR-NOR gate combination (NOR2+NOR2) having two NOR gates is actualized in the super cell.

FIG. 13 illustrates logic of a super cell having a NAND-NOR gate combination (NAND2+NOR2) implemented therein and a logic circuit thereof according to an embodiment.

Referring to FIG. 13, the contact conductive layer 20a of the VDD line 10 and the contact conductive layer 24a positioned in the first row and first column of the PMOS active area 14 to the left side of the first gate 18a are coupled through a metal M. Furthermore, the contact conductive layer 20c of the VDD line 10 and the contact conductive layer 24c positioned in the first row and third column of the PMOS active area 14 between the second and third gates 18b and 18c are coupled through a metal M.

Furthermore, the contact conductive layer 22c of the VSS line 12 and the contact conductive layer 26h positioned in the second row and third column of the NMOS active area 16 between the second and third gates 18b and 18c are coupled through a metal M. Here, the first gate 18a and the second gate 18b serve as a signal input terminal A and a signal input terminal B, respectively.

Furthermore, when the contact conductive layers 24b, 24g, and 241 positioned in the second column of the PMOS active area 14 and the contact conductive layers 26a and 26f positioned in the first column of the NMOS active area 16 are coupled through a metal M, a NAND2 gate having two signal input terminals A and B and one signal output terminal Y1 is actualized.

The contact conductive layer 22e of the VSS line 12 and the contact conductive layer 26j positioned in the second row and fifth column of the NMOS active area 16 to the right side of the fourth gate 18d are coupled through a metal M.

Furthermore, when the contact conductive layers 24e, 24j, and 24o positioned in the fifth column of the PMOS active area 14 and the contact conductive layers 26d and 26i positioned in the fourth column of the NMOS active area 16 between the third and fourth gates 18c and 18d are coupled through a metal M, a NOR2 gate having two signal input terminals C and D and one signal output terminal Y2 is actualized.

Here, when the NOR2 gate is formed to the right side of the NAND2 gate, the NAND-NOR gate combination (NAND2+NOR2) is actualized in the super cell.

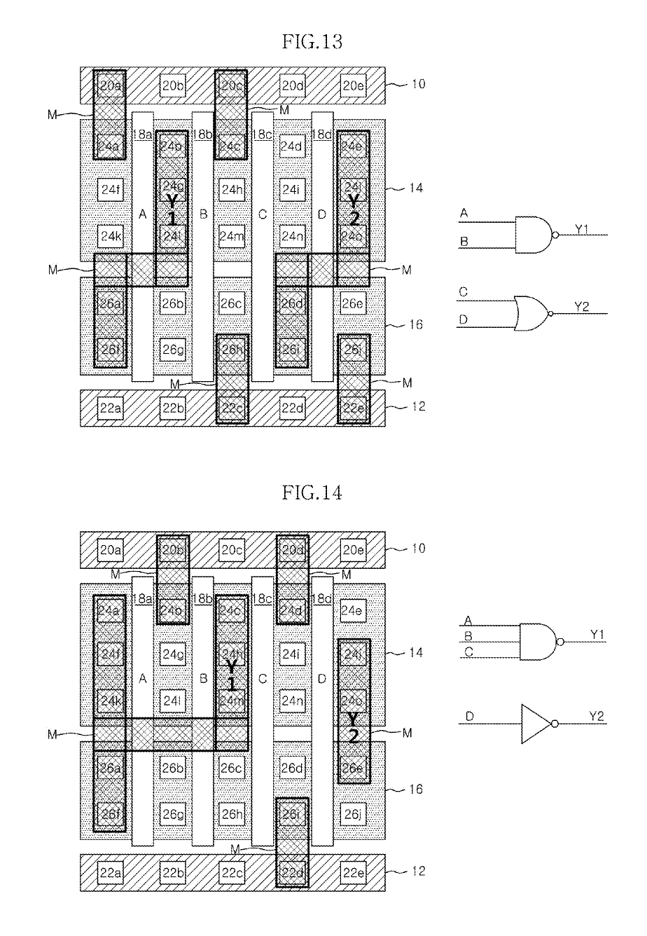

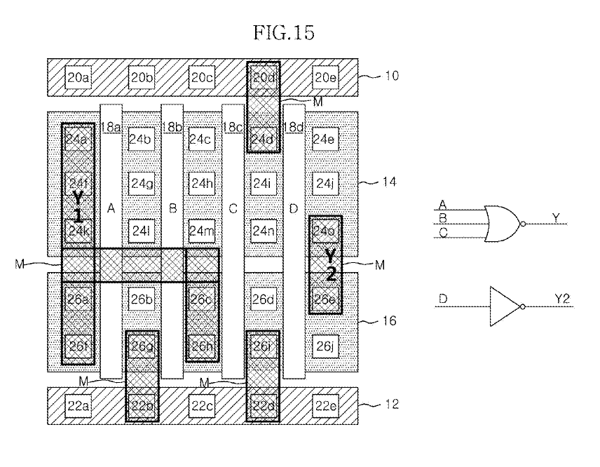

FIG. 14 illustrates logic of a super cell having a NAND-INV gate combination (NAND3+INV) implemented therein and a logic circuit thereof according to an embodiment.

Referring to FIG. 14, the contact conductive layer 20b of the VDD line 10 and the contact conductive layer 24b positioned in the first row and second column of the PMOS active area 14 between the first and second gates 18a and 18b are coupled through a metal M. Furthermore, the contact conductive layer 20d of the VDD line 10 and the contact conductive layer 24d positioned in the first row and fourth column of the PMOS active area 14 between the third and fourth gates 18c and 18d are coupled through a metal M.

Furthermore, the contact conductive layer 22d of the VSS line 12 and the contact conductive layer 26i positioned in the second row and fourth column of the NMOS active area 16 between the third and fourth gates 18c and 18d are coupled through a metal M. Here, the first gate 18a, the second gate 18b, and the third gate 18c serve as a signal input terminal A, a signal input terminal B, and a signal input terminal C, respectively.

Furthermore, when the contact conductive layers 24a, 24f, and 24k positioned in the first column of the PMOS active area 14, the contact conductive layers 24c, 24h, and 24m positioned in the third column of the PMOS active area 14, and the contact conductive layers 26a and 26f positioned in the first column of the NMOS active area 16 are coupled through a metal M, a NAND3 gate having three signal input terminals A, B, and C and one signal output terminal Y1 is actualized.

Meanwhile, when the contact conductive layers 24j and 24o positioned in the fifth column of the PMOS active area 14 and the contact conductive layer 26e positioned in the fifth column of the NMOS active area 16 are coupled through a metal M, an INV gate having one signal input terminal D and one signal output terminal Y2 is actualized.

Here, when the INV gate is formed in the right side of the NAND3 gate, the NAND-INV gate combination (NAND3+INV) is actualized in the super cell.

FIG. 15 illustrates logic of a super cell having a NOR-INV gate combination (NOR3+INV) implemented therein and a logic circuit thereof according to an embodiment.

Referring to FIG. 15, the contact conductive layer 20d of the VDD line 10 and the contact conductive layer 24d positioned in the first row and fourth column of the PMOS active area 14 between the third and fourth gates 18c and 18d are coupled through a metal M.

Furthermore, the contact conductive layer 22b of the VSS line 12 and the contact conductive layer 26g positioned in the second row and second column of the NMOS active area 16 between the first and second gates 18a and 18b are coupled through a metal M. Furthermore, the contact conductive layer 22d of the VSS line 12 and the contact conductive layer 26i positioned in the second row and fourth column of the NMOS active area 16 between the third and fourth gates 18c and 18d are coupled through a metal M. Here, the first gate 18a, the second gate 18b, and the third gate 18c serve as a signal input terminal A, a signal input terminal B, and a signal input terminal C, respectively.

Furthermore, when the contact conductive layers 24a, 24f, and 24k positioned in the first column of the PMOS active area 14, the contact conductive layers 26a and 26f positioned in the first column of the NMOS active area 16, and the contact conductive layers 26c and 26h positioned in the third column of the NMOS active area 16 are coupled through a metal M, a NOR3 gate having three signal input terminals A, B, and C and one signal output terminal Y1 is actualized.

When the contact conductive layer 24o positioned in third row and the fifth column of the PMOS active area 14 and the contact conductive layer 26e positioned in the first row and the fifth column of the NMOS active area 16 are coupled through a metal M, an INV gate having one signal input terminal D and one signal output terminal Y2 is actualized.

Here, when the INV gate is formed to the right side of the NOR3 gate, the NOR-INV gate combination (NOR3+INV) is actualized in the super cell.

As illustrated in FIGS. 4 to 15, the supper cell according to an embodiment of the present invention may be used to freely implement the gate combinations (NAND-NAND(NAND2+NAND2), NOR-NOR(NOR2+NOR2), NAND-NOR(NAND2+NOR2), NAND-inverter(NAND3+INV), and NOR-inverter(NOR3+INV)) as well as the one-input gate INV, the two-input gates NAND2 and NOR2, the three-input gates NAND3 and NOR3, and the four-input gates NAND4 and NOR4, through metal programming.

During the processes of implementing the one to four-input gates and the gate combinations illustrated in FIGS. 4 to 15, one or more of the contact conductive layers formed in the PMOS active area and one or more of the contact conductive layers formed in the NMOS active area may be coupled to form an output terminal. For example, a plurality of contact conductive layers formed in the PMOS active area and the NMOS active area, respectively, may be coupled. In this case, it is possible to obtain an effect of further reducing the resistance of the output terminal from when the contact conductive layers formed in the PMOS active area and the NMOS active area, respectively, are coupled by ones.

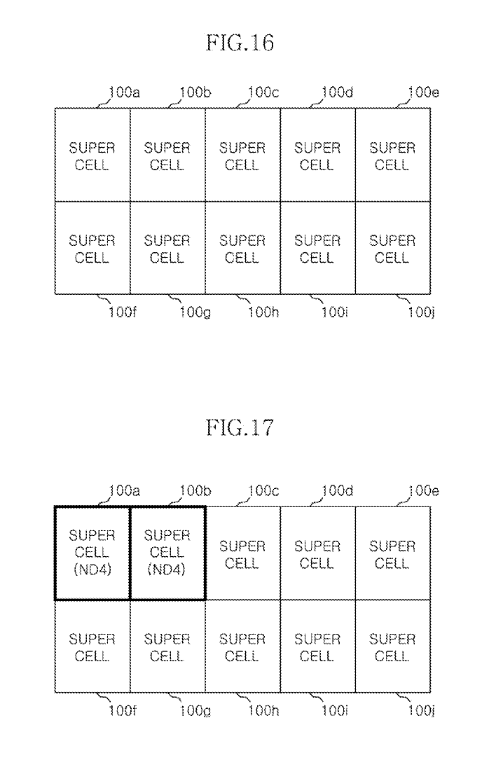

FIG. 16 illustrates a layout of super cells according to an embodiment. FIG. 17 illustrates an example in which the super cells of FIG. 16 are utilized.

Referring to FIG. 16, 10 super cells 100a, 100b, 100c, 100d, 100e, 100f, 100g, 100h, 100i, and 100j, each of which is illustrated in FIG. 3, are arranged in a 2×5 matrix.

In an embodiment of the present invention, a plurality of super cells may be arranged to easily change the logic of a gate only through metal programming. Therefore, the degree of freedom of a design may be increased, and the time and cost required for circuit design revision may be minimized.

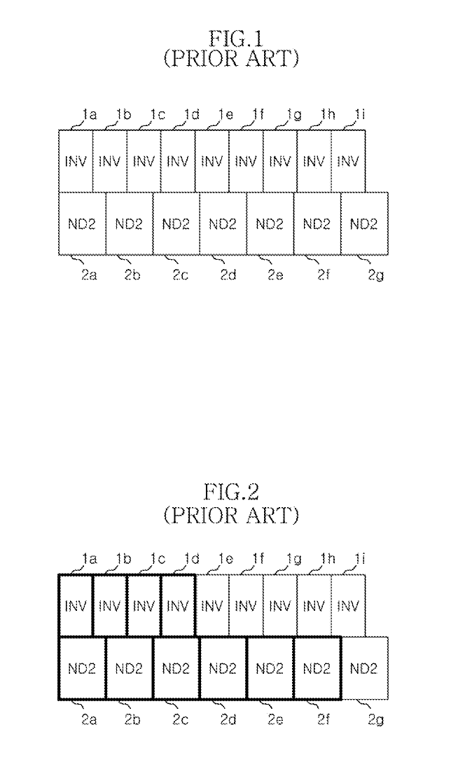

For example, when two NAND4 gates are needed, a method of coupling four INV gates and six NAND2 gates through metals was used in the conventional semiconductor memory apparatus as described in FIG. 2. Using the prior art configuration when a NAND4 gate is additionally needed, full revision should be performed instead of metal revision, due to the lack of INV gates. Accordingly, the design time is increased, and a lot of cost is required.

In an embodiment of the present invention, however, two NAND4 gates may be implemented by using the super cells 100a and 100b illustrated in FIG. 17. Furthermore, although three or more (10 at most) NAND4 gates are additionally required, the other super cells 100c to 100j where gate logic correction has not been performed may be used to freely implement a necessary number of NAND4 gates.

In the conventional semiconductor memory apparatus, when spare logic gates which were previously arranged by a designer are completely used, circuit correction is impossible in the metal revision step. Therefore, full revision should be performed.

However, when the super cell according to an embodiment of the present invention is used, the logic of the gate may be easily changed simply through metal programming which couples a plurality of contact conductive layers through a metal. The plurality of contact conductive layers are formed in the power lines VDD and VSS and the active areas, in order to prepare for circuit design revision. Therefore, circuit correction may be covered at the metal revision step. Accordingly, since full revision does not need to be performed unlike the conventional semiconductor memory apparatus, a turn around time (TAT) may be shortened, and a mask cost may be reduced.

While certain embodiments have been described above, it will be understood to those skilled in the art that the embodiments described are by way of example only. Accordingly, the method and structure described herein should not be limited based on the described embodiments. Rather, the method and structure described herein should only be understood in light of the claims that follow when taken in conjunction with the above description and accompanying drawings.

What is claimed is:

1. A method for implementing a spare logic of a semiconductor memory apparatus, comprising the steps of:
forming one or more contact conductive layers, which are independent, in a power line and an active area, respectively; and
performing metal programming on the contact conductive layers formed in the power line and the active area to electrically couple the contact conductive layers formed in the power line and the active area.

2. The method according to claim 1, wherein the power line comprises a VDD line and a VSS line.

3. The method according to claim 2, wherein the active area comprises a PMOS active area and an NMOS active area.

4. The method according to claim 3, wherein one or more contact conductive layers of the power line and one or more contact conductive layers of the active area are coupled to each other.

5. The method according to claim 4, wherein one or more contact conductive layers of the PMOS active area and one or more contact conductive layers of the NMOS active area are coupled to each other.

6. The method according to claim 5, wherein the contact conductive layers of the power line and the active area are electrically coupled to form a one-input gate, a two-input gate, a three-input gate, or a four-input gate.

7. The method according to claim 6, wherein at least one of the one-input gate, the two-input gate, the three-input gate, and the four-input gate comprises at least one contact conductive layer from at least one of the NMOS active area, the PMOS active area, the VDD line and the VSS line.

8. The method according to claim 5, wherein the contact conductive layers of the power line and the active area are electrically coupled to form a NAND-NAND gate combination, a NOR-NOR gate combination, a NAND-NOR gate combination, a NAND-INV gate combination, or a NOR-INV gate combination.

9. The method according to claim 5, further comprising forming an output terminal by coupling a plurality of contact conductive layers of at least one of the PMOS active area and the NMOS active area.

10. The method according to claim 5, further comprising forming the PMOS active area with a same number of columns ad the NMOS active area and a different number of rows as the NMOS active area.

11. A spare logic of a semiconductor memory apparatus, comprising:
a power line having one or more contact conductive layers formed therein, on which metal programming is to be performed; and
an active area having one or more contact conductive layers formed therein, which are configured to be electrically coupled to the one or more contact conductive layers of the power line through the metal programming.

12. The spare logic according to claim 11, wherein the power line comprises a VDD line and a VSS line.

13. The spare logic according to claim 11, wherein the active area comprises a PMOS active area and an NMOS active area.

14. The spare logic according to claim 13, wherein the one or more contact conductive layers of the power line and the one or more contact conductive layers of the active area are coupled to each other.

15. The spare logic according to claim 14, wherein one or more contact conductive layers of the PMOS active area and one or more contact conductive layers of the NMOS active area are coupled to each other.

16. The spare logic according to claim 15, wherein the contact conductive layers of the power line and the active area are electrically coupled to form a one-input gate, a two-input gate, a three-input gate, or a four-input gate.

17. The spare logic according to claim 16, wherein at least one of the one-input gate, the two-input gate, the three-input gate, and the four-input gate comprises at least one contact conductive layer from at least one of the NMOS active area, the PMOS active area, the VDD line and the VSS line.

18. The spare logic according to claim 15, wherein the is contact conductive layers of the power line and the active area are electrically coupled to form a NAND-NAND gate combination, a NOR-NOR gate combination, a NAND-NOR gate combination, a NAND-INV gate combination, or a NOR-INV gate combination.

19. The spare logic according to claim 15, wherein a plurality of contact conductive layers of at least one of the PMOS active area and the NMOS active area are coupled to form an output terminal.

20. The spare logic according to claim 15, wherein the NMOS active area is comprised of a same number of columns as the PMOS active area and a different number of rows as the PMOS active area.
